(19) United States
(12) Patent Application Publication
(10) Pub. No.: US 2007/0278483 A1
(43) Pub. Date: Dec. 6, 2007

(54) Light emitting device and method of manufacturing the same

(75) Inventor: Goro Narita, Gunma-ken (JP)

Correspondence Address: MORRISON & FOERSTER LLP, 1650 TYSONS BOULEVARD, SUITE 400, MCLEAN, VA, 22102, US

(73) Assignee: Element Denshi Co., Ltd., Takasaki-shi (JP)

(21) Appl. No.: 11/802,562

(22) Filed: May 23, 2007

(30) Foreign Application Priority Data
May 24, 2006 (JP) 2006-144613

(51) Int. Cl. H01L 29/08

(52) U.S. Cl. 257/40

(57) ABSTRACT

A light emitting device of the present invention includes a first conductive film, a second conductive film, a half-etching hole, a light emitting element, through-hole electrodes, conductive metal layers, metallic wires and a transparent protective resin. The first conductive film is thick, and is provided on one main surface of an insulative substrate. The second conductive film is thin, and is provided on an opposite main surface of the insulative substrate. The half-etching hole is provided in the first conductive film. The through-hole electrodes connect the first conductive film with the second conductive film. Light emitted from the light emitting element is reflected by the conductive metal layer provided on a curved surface of the half-etching hole. Moreover, the conductive metal layers are bonded with the metallic wires, respectively.

### BACKGROUND OF THE INVENTION

Priority is claimed to Japanese Patent Application Number JP2006-144613 filed on May 24, 2006, the disclosure of which is incorporated herein by reference in its entirety.

1. Field of the Invention

The present invention relates to a light emitting device and a method of manufacturing the same, in which a half-etching hole is formed in a thick conductive film, in which a conductive metal layer used for wire bonding is then formed on the side surface of the half-etching hole, and in which the conductive metal layer is to be also utilized as a reflector.

2. Description of the Related Art

FIG. 6 shows a light emitting device. In the light emitting device, light emitted from a light emitting element is prevented from being absorbed into a base substrate. Thereby, loss of the emitted light is reduced. As a result, a total luminance is improved.

This light emitting device includes a light emitting element 100, a base substrate 200, a pair of substrate electrode portions 300, connection electrode portions 400, a light reflecting portion 500, a hole 600 and a plating layer 700. The light emitting element 100 is a group III nitride compound semiconductor light emitting element. The base substrate 200 is an insulative substrate made of a resin such as polyimide resin, glass epoxy resin, BT resin or the like. Each of the pair of substrate electrode portions 300 is made of a copper foil film, and is formed on the base substrate 200 so as to extend from an upper surface to a lower surface of the base substrate 200. The light reflecting portion 500 is made of a copper foil film, and is formed on the lower surface of the base substrate 200, which surface is opposite to that on which the light emitting element 100 is mounted. The hole 600 is formed by opening an insulative portion of the base substrate 200 in the thickness direction of the base substrate 200. Here, across the insulative portion, the pair of substrate electrode portions 300 face each other. The plating layer 700 is made of gold or silver, and is formed on the inner peripheral surface of the hole 600, and on a surface of the light reflecting portion 500, which surface is exposed through the hole 600. Moreover, each of the connection electrode portions 400 is an electrode made of a conductive film which is electrically connected to the corresponding substrate electrodes 300. The connection electrode portions 400 are provided on the back surface of the base substrate 200. The connection electrode portions 400 are mounted on a device substrate such as a mother board. This technology is described for instance in Japanese Patent Application Publication No. 2005-175387.

However, the above-described light emitting device has the following problems.

The hole is formed in the base substrate as corresponding to the back surface of the light emitting element that is mounted. In addition, light emitted from the lower side of the light emitting element is reflected upward. For this reason, this light emitting device is poor in heat dissipation, and is thus hard to be in use for a long time.

Moreover, the hole is formed by cutting the base substrate in the thickness direction of the base substrate. For this reason, it is difficult to improve the amount of reflected light, since the hole is covered with the light emitting element.

Furthermore, in order to improve luminance of the light emitting element, the following two steps are required in manufacturing the light emitting device. One is a step of forming a concave portion by etching the base substrate. The other one is a step of forming the light reflecting portion on the inner peripheral surface of the hole, or on one surface of the base substrate, which is opposite to the other surface thereof on which the light emitting element is mounted. This leads to a problem in which the manufacturing process becomes complicated.

### SUMMARY OF THE INVENTION

The present invention provides a light emitting device comprising, an insulating substrate comprising a first surface and a second surface opposite from the first surface, a first conductive film disposed on the first surface and having a dent portion comprising a bottom and sidewall and denting toward the substrate, a second conductive film disposed on the second surface and thinner than the first conductive film, a light emitting element disposed in the dent portion of the first conductive film, a through hole electrode disposed in a through hole formed in the substrate and connecting the first and second conductive films, a first metal layer disposed on the sidewall of the dent portion so as to reflect light emitted from the light emitting element, a second metal layer disposed on a top surface of the through-hole electrode; and a metal wire connecting an electrode of the light emitting element and the second metal layer.

The present invention also provides a method of manufacturing a light emitting device, comprising providing an insulating substrate comprising a first conductive film disposed on a first surface thereof and a second conductive film disposed on a second surface thereof and thinner than the first conductive film, forming a plurality of through holes in the substrate so as to penetrate though the substrate and the first and second conductive films, forming a plurality of through hole electrodes in corresponding through holes by plating so as to connect electrically the first and second conductive films, etching the first conductive film to define a plurality of cells, forming a hole in the first conductive film for each of the cell, depositing by plating a metal for bonding on a top surface of each of the through hole electrodes and a surface of each of the holes, attaching a light emitting element to each of the holes on which the metal for bonding is deposited, bonding, in each of the cells, an end of a metal wire to an electrode of the light emitting element and another end of the metal wire to a corresponding through hole electrode on which the metal for bonding is deposited, covering the light emitting elements and the metal wires with a resin, and cutting the substrate so as to produce separated light emitting devices.

### BRIEF DESCRIPTION OF THE DRAWINGS

FIG. 1A is a top view of a light emitting device of an embodiment of the present invention, and FIG. 1B is a cross-sectional view of the light emitting device.

FIG. 2A is a top view of a mounting substrate used in the embodiment of the present invention, and FIG. 2B is a bottom view of the mounting substrate.

FIGS. 3A to 3E are cross-sectional views for explaining a method of manufacturing a light emitting device of the embodiment of the present invention.

FIGS. 4A to 4C are cross-sectional views for explaining the method of manufacturing a light emitting device of the embodiment of the present invention.

FIG. 5 is a top view of the mounting substrate of the embodiment of the present invention.

FIG. 6 is a cross-sectional view for explaining a conventional light emitting device.

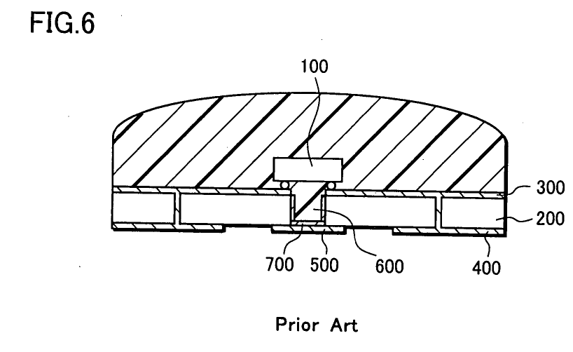

### DESCRIPTION OF THE PREFERRED EMBODIMENT(S)

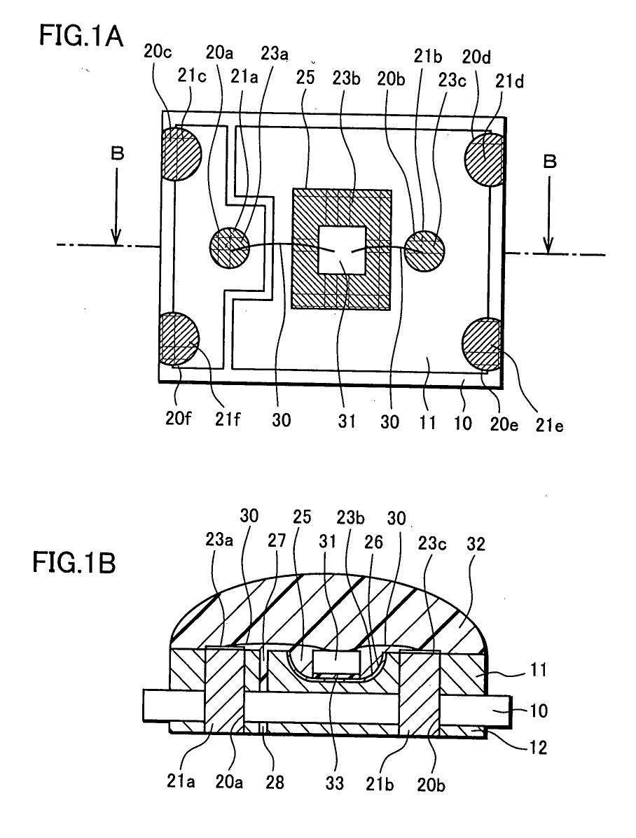

At first, a light emitting device according to an embodiment of the present invention is shown in FIGS. 1A and 1B. FIG. 1A is a top view of the light emitting device, and FIG. 1B is a cross-sectional view of the light emitting device.

The light emitting device of the embodiment includes an insulative substrate 10, a first conductive film 11, a second conductive film 12, a half-etching hole 25, a light emitting element 31, through-hole electrodes 21a, 21b, 21c, 21d, 21e and 21f, conductive metal layers 23a, 23b and 23c, metallic wires 30, and a transparent protective resin 32. The first conductive film 11 is thick, and is provided to one main surface of the insulative substrate 10. The second conductive film 12 is thin, and is provided to an opposite main surface of the insulative substrate 10. The half-etching hole 25 is formed in the first conductive film 11. Each of the through-hole electrodes 21a to 21f connects the first conductive film 11 to the second conductive film 12.

As the insulative substrate 10, a glass epoxy substrate or a glass polyimide substrate is preferably used. The insulative substrate 10 serves as a supporting substrate for the first and second conductive films 11 and 12.

The first and second conductive films 11 and 12 are copper foils, and are pressed and bonded respectively to both surfaces of the insulative substrate 10 with an adhesive. The first conductive film 11 is thicker than the light emitting element 31. The second conductive film 12 is much thinner than the first conductive film 11 since the second conductive film 12 serves as a wiring.

The half-etching hole 25 is provided to a substantially center portion of the first conductive film 11, and is formed by chemical etching. For this reason, the bottom of the half-etching hole 25 is positioned in the middle of the first conductive film 11 in the thickness direction thereof, and in most cases, is positioned at the half of the depth of the first conductive film 11 (etching in this manner is referred to as half-etching). The half-etching hole 25 is formed into a square, a circle, an ellipse, a polygon or the like, which is larger in size than the light emitting element 31 to be housed therein. On the side surface of the half-etching hole 25, a concave curved surface 26 is formed by chemical etching.

The light emitting element 31 is a group III nitride compound semiconductor light emitting element. As the group III nitride compound, gallium nitride compound is preferably used. The light emitting element 31 used here has a shape in which the lower surface thereof has 0.15 mm on each side, and the height thereof is 90 μm. The light emitting element 31 is bonded and fixed to the bottom of the half-etching hole 25 with an adhesive 33. When a cathode is led out from the lower surface of the light emitting element 31, a conductive paste is preferably used as the adhesive 33. When a cathode is led out from the upper surface of the light emitting element 31, an insulative paste is preferably used as the adhesive 33.

The through-hole electrodes 21a to 21f are formed of metallic layers of copper or the like, which are formed by through-hole plating, in through holes 20a, 20b, 20c, 20d, 20e and 20f, respectively. The through holes 20a and 20b are provided respectively on the left and right sides of the half-etching hole 25. The through holes 20c to 20f are provided respectively near the four corners of the light emitting device in a manner that each of the through holes 20c to 20f straddles the peripheral edge of the insulative substrate 10. The through-hole electrodes 21a, 21c and 21f form an electrode on the anode side of the light emitting element 31 together with the first and second conductive films 11 and 12. The through-hole electrodes 21b, 21d and 21e form an electrode on the cathode side of the light emitting element 31 together with the first and second conductive films 11 and 12. On both of the anode and cathode sides, the first conductive film 11 and the second conductive film 12 are electrically connected to each other via the corresponding three through-hole electrodes.

Each of the conductive metal layers 23a to 23c is formed of a bondable metal. The conductive metal layers 23a to 23c are selectively deposited by plating respectively on the through-hole electrode 21a, on the bottom and the side surface of the half-etching hole 25, and on the through-hole electrode 21b. For the conductive metal layers 23a to 23c, any one of gold, silver and nickel, which are bondable, is selected. Here, silver is used. On both of the bottom and the side surface of the half-etching hole 25, the conductive metallic layer 23b is deposited. Part of the conductive metallic layer 23b, which is deposited on the curved surface 26 on the side, serves as a reflector. Since the curved surface 26 is concave, the curved surface 26 efficiently reflects light emitted from the light emitting element 31 in a direction (the upward direction) in which the light is to be focused.

One of the metallic wires 30 electrically connects the anode electrode on the surface of the light emitting element 31 to the conductive metallic layer 23a on the through-hole electrode 21a, and the other one of the metallic wires 30 electrically connects the cathode electrode on the surface of the light emitting element 31 to the conductive metallic layer 23c on the through-hole electrode 21b.

The transparent protective resin 32 covers the entirety of the light emitting device, and protects the light emitting element 31 and the metallic wires 30 while serving as a lens for the light emitting element 31.

The half-etching hole 25 has the following shape. Specifically, the diameter of an opening of the half-etching hole 25 is 0.3 mm, while the diameter of the bottom thereof is 0.16 mm. In addition, the height of the half-etching hole 25 is 0.1 mm. Moreover, the tilt angle of the curved surface 26 of the half-etching hole 25 is 125 degrees.

On the first conductive film 11, a strip-shaped pattern is formed, as shown in FIG. 1A. In the strip-shaped pattern, a convex pattern is formed on the left side of the center, and a concave pattern is formed so as to face the convex pattern. By forming the concave pattern larger than the convex pattern, the surroundings of the half-etching hole 25 can be widened. This makes it possible to improve the heat dissipation of the light emitting element 31 bonded and fixed to the bottom of the half-etching hole 25.

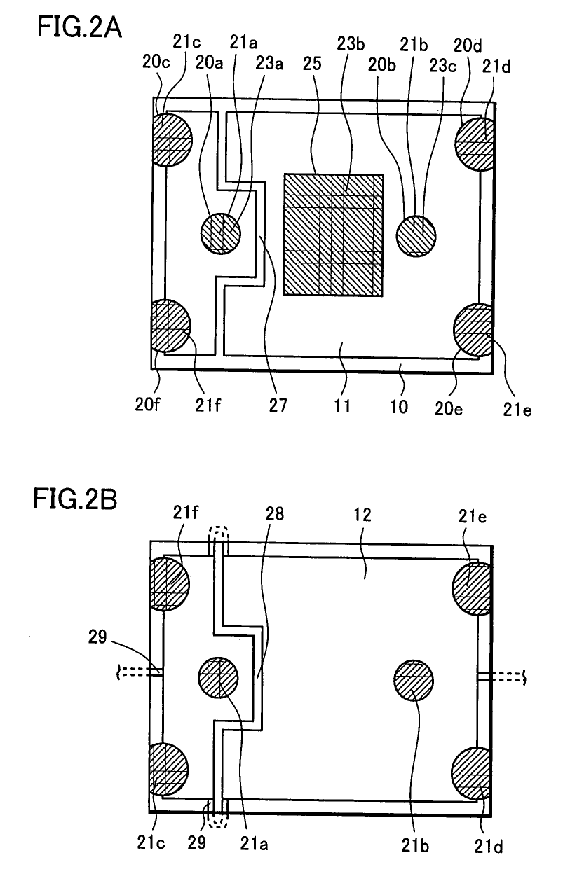

Next, an individual cell of the embodiment of the present invention is shown in FIGS. 2A and 2B. FIG. 2A is a top view of the cell, and FIG. 2B is a bottom view of the cell.

In the cell, the first conductive film 11, which is thick, and the second conductive film 12, which is thin, are attached respectively to upper and lower surfaces of the insulative substrate 10 so as to be integrated. In a substantially center of the first conductive film 11, the half-etching hole 25 is formed, in which the light emitting element 31 is mounted. Just on the left side of the half-etching hole 25, an isolating groove 27 is provided, so that the isolating groove 27 divides the first conductive film 11 into left and right regions. The left and right regions of the first conductive film 11 are to serve respectively as the anode electrode and the cathode electrode. The second conductive film 12 is also divided into left and right regions by an isolating groove 28, as corresponding to the first conductive film 11. The left and right regions of the second conductive film 12 are also to serve respectively as an anode electrode and a cathode electrode.

The through holes 20a and 20b are formed near the half-etching hole 25, and respectively on the left and right sides of the half-etching hole 25. Moreover, in the through holes 20a and 20b, the through-hole electrodes 21a and 21b are formed, respectively. Part of the first conductive film 11 and part of the second conductive film 12, which are to be the anode electrode, are electrically connected to each other by the through-hole electrode 21a. On the other hand, part of the first conductive film 11 and part of the second conductive film 12, which are to be the cathode electrode, are also electrically connected to each other by the through-hole electrode 21b. In the peripheral edge of the cell, the through holes 20c, 20d, 20e and 20f are formed, each of which is slightly larger than the above-described through holes 20a and 20b. The through-hole electrodes 21c, 21d, 21e and 21f are formed respectively in the through holes 20c to 20f. With the through-hole electrodes 21c and 21f, part of the first conductive film 11 and part of the second conductive film 12, which are to be the anode electrode, are also electrically connected to each other. With the through-hole electrodes 21d and 21e, part of the first conductive film 11 and part of the second conductive film 12, which are to be the cathode electrode, are also electrically connected to each other. As a result of the configuration, through-hole connections are surely formed in the three portions on each side of the anode and cathode electrodes.

In the mounting substrate prepared in the embodiment, the first conductive film 11, which is thicker than the light emitting element 31, and the second conductive film 12, which is thin, are attached respectively to the upper and lower surfaces of the insulative substrate 10. The half-etching hole 25 is formed by half-etching the first conductive film 11 from the surface thereof. The half-etching hole 25 is formed so as to have a depth with which the light emitting element 31 can be fit into the half-etching hole 25. Incidentally, it is not absolutely necessary that the light emitting element 31 fits fully into the half-etching hole 25.

As the insulative substrate 10, a glass epoxy substrate or a glass polyimide substrate is preferably used. In some cases, a fluorine resin substrate, a glass PPO substrate or a ceramic substrate may be employed. Moreover, a flexible sheet or a film may also be used. In the embodiment, the glass epoxy substrate having a thickness of about 200 μm is employed.

As the first and second conductive films 11 and 12, any metal can be employed as long as the metal can be etched. In the embodiment, a metallic foil made of copper is employed. In addition, as the first conductive film 11, a copper foil having a film thickness of about 175 μm is employed. The thickness of the first conductive film 11 is determined so as to correspond to the depth of the half-etching hole 25. It is possible to employ a conductive film having a thickness of up to about 230 μm. Accordingly, the thickness of the first conductive film 11 can be determined according to the depth of the half-etching hole 25.

As the second conductive film 12, a conductive film having a thickness necessary for wiring is used. In the embodiment, the second conductive film 12 is formed so as to have a thickness of about 18 μm. The thickness of wiring may be determined as appropriate according to a current capacity of each circuit element to be mounted, and the like.

The conductive metal layers 23a, 23b and 23c are formed so as to overlap respectively the through-hole electrode 21a, the inner surface of the half-etching hole 25 and the through-hole electrode 21b. For the conductive metal layers 23a to 23c, any one of gold, silver and nickel, which are bondable, is selected. Each of the conductive metal layers 23a to 23c is formed by electrolytic plating so as to have a thickness of 1 to 3 μm.

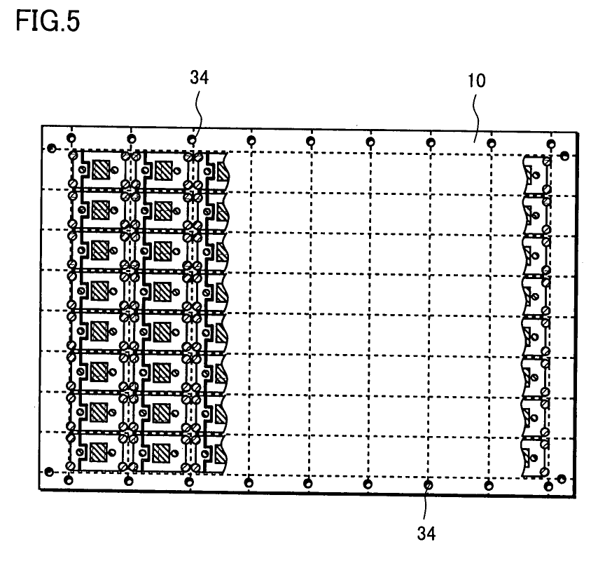

A large number of above-described cells are arranged in a matrix on a large mounting substrate, as shown in FIG. 5.

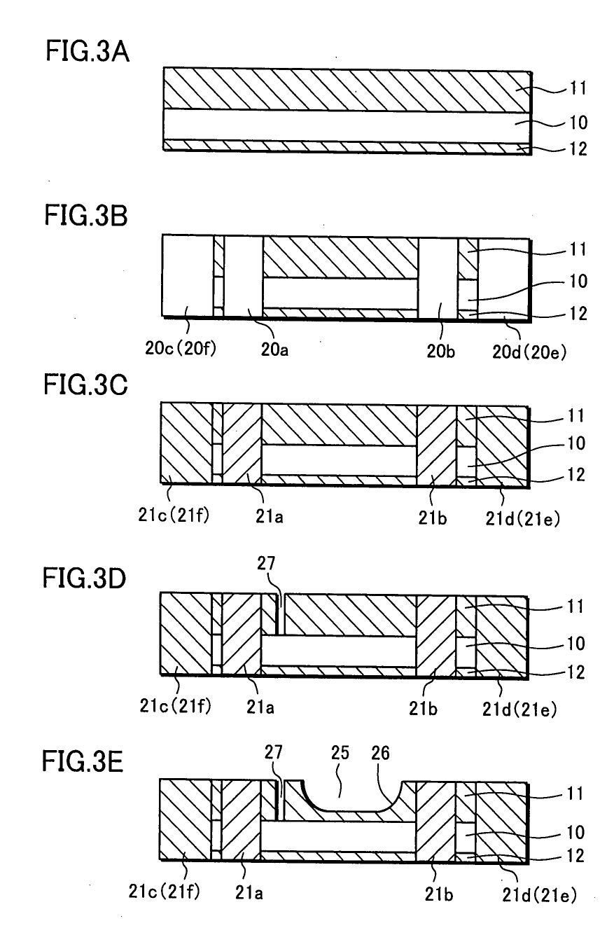

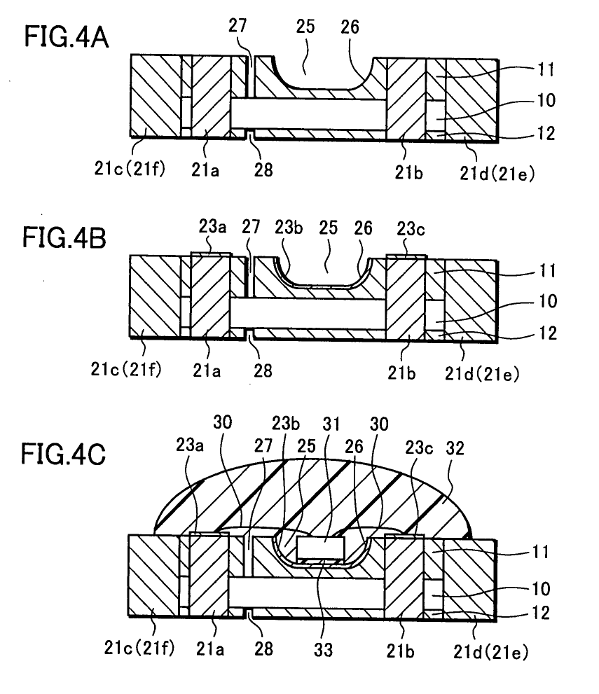

Subsequently, description will be given below of a method of manufacturing a light emitting device according to the embodiment of the present invention, with reference to FIGS. 3 and 4.

A method of manufacturing a light emitting device according to an embodiment of the present invention includes the following steps. In a first step, an insulative substrate is prepared. Specifically, a first conductive film, which is thick, is adhered on one main surface of the insulative substrate. In addition, a second conductive film, which is thinner than the first conductive film, is adhered on an opposite main surface of the insulative substrate. In a second step, through holes are formed respectively in predetermined positions in a manner that each of the through holes penetrates the insulative substrate and the first and second conductive films. In a third step, through-hole electrodes are formed respectively in the through holes by through-hole plating so that each of the through-hole electrodes electrically connects the first and second conductive films to each other. In a fourth step, by etching the first conductive film, a large number of patterns of cells, in each of which a light emitting element is to be mounted, are formed. In a fifth step, a half-etching hole having a curved side surface is formed in each cell by half-etching from the surface of the first conductive film. In a sixth step, conductive metal layers, which are bondable, are selectively deposited by plating respectively on the surfaces of the half-etching hole and of the through-hole electrodes. In a seventh step, the light emitting element is bonded and fixed to the bottom of the half-etching hole in each cell. In an eighth step, electrodes of the light emitting element are connected respectively to the conductive metal layers by wire bonding with metallic wires. In a ninth step, the light emitting element and the metallic wires are covered with a transparent resin. In a tenth step, an individual light emitting device is separated in each cell by dicing.

In the first step of the embodiment of the present invention, a glass epoxy substrate, which is to be an insulative substrate 10, is prepared. As shown in FIG. 3A, on one main surface of the insulative substrate 10, a first conductive film 11 made of copper or the like is adhered. In addition, on an opposite main surface of the insulative substrate 10, a second conductive film 12 made of copper or the like is adhered Here, the first conductive film 11 is thicker than a light emitting element, and the second conductive film 12 is thinner than the first conductive film 11.

As the insulative substrate 10, a glass epoxy substrate or a glass polyimide substrate is preferably used. However, in some cases, a fluorine resin substrate, a glass PPO substrate or a ceramic substrate may be employed. Moreover, a flexible sheet or a film may also be used. In the embodiment, the glass epoxy substrate having a thickness of about 200 μm is employed.

As the first and second conductive films 11 and 12, any metal can be employed as long as the metal can be etched. In the embodiment, a metallic foil made of copper is employed. In addition, as the first conductive film 11, a copper foil having a film thickness of about 175 μm is employed. The thickness of the first conductive film 11 is determined so as to correspond to the depth of a half-etching hole 25. It is possible to employ a conductive film having a thickness of up to about 230 μm. Accordingly, the depth of the half-etching hole 25 can be determined according to the thickness of the first conductive film 11.

As the second conductive film 12, a conductive film having a thickness corresponding to the height of wirings is used. In the embodiment, the second conductive film 12 is formed so as to have a thickness of about 18 μm. The thickness of wirings may be determined as appropriate according to a current capacity of each circuit element to be mounted, and the like.

In the second step of the embodiment of the present invention, as shown in FIG. 3B, through holes are formed respectively in predetermined positions, so that each of the through holes penetrates the insulative substrate and the first and second conductive films.

In the second step, through holes 20a, 20b, 20c, 20d, 20e and 20f for forming through-hole electrodes are formed by using a NC machine tool with a drill or the like. Moreover, the through holes 20a to 20f are formed so as to penetrate the first and second conductive films 11 and 12, and the insulative substrate 10. The through holes 20a and 20b are formed respectively on the left and right side of the half-etching hole shown in FIG. 2A, so that each of the through holes 20a and 20b has a diameter of 0.3 mm. In addition, each of the through holes 20c to 20f is formed with a diameter of 0.4 mm, in a manner that each of the through holes 20c to 20f straddles the peripheral edge of the insulative substrate 10. Although, in FIGS. 3A to 3E, the through holes 20a to 20f are shown in the same cross-sectional view for convenience, the actual arrangement of these through holes 20a to 20f are that shown in FIG. 2A.

In the third step of the embodiment of the present invention, as shown in FIG. 3C, through-hole electrodes 21a, 21b, 21c, 21d, 21e and 21f are formed respectively in the through holes by through-hole plating. The through-hole electrodes 21a to 21f are formed so that each of the through-hole electrodes 21a to 21f electrically connects the first and second conductive films 11 and 12 to each other.

In the third step, the through-hole electrodes 21a, 21b, 21c, 21d, 21e and 21f, each having a film thickness of about 20 μm, are formed respectively on the inner walls of the through holes 20a to 20f. Specifically, the entire body is immersed in a palladium solution, and then electroless copper plating and electrolytic plating are applied to the inner surfaces of the through holes 20a to 20f by using the first and second conductive films 11 and 12 as electrodes.

In the fourth step of the embodiment of the present invention, as shown in FIG. 3D, a large number of patterns of cells, in each of which a light emitting element 31 is to be mounted, are formed by etching the first conductive film 11.

In the fourth step, firstly, the first and second conductive films 11 and 12 on the insulative substrate 10 are covered respectively with resist layers (not illustrated). Then, a strip-shaped pattern shown in FIG. 2A is formed on the first conductive film 11 by exposure and development. Thereafter, by using the rest of the resist layer as a mask, the first conductive film 11 is etched, and thereby the pattern of cell in which the light emitting element 31 is to be mounted is formed. In this manner, a large number of patterns of cells are formed in a matrix. When the first conductive film 11 is made of copper, ferric chloride is used as an etching solution. Subsequently, the resist layer is removed. The shape of the pattern of each cell has already been described with reference to FIG. 2A, and is accordingly omitted here. Incidentally, an isolating groove 27 is also formed together in this step.

In the fifth step of the embodiment of the present invention, as shown in FIG. 3E, the half-etching hole 25 is formed by half etching the first conductive film 11 of each cell from the surface of the first conductive film 11. The half-etching hole 25 is formed so as to have a curved side surface 26.

In the fifth step, the first and second conductive films 11 and 12 on the insulative substrate 10 are covered again respectively with resist layers (not illustrated). Then, a circular pattern shown in FIG. 2A is formed on the first conductive film 11 around the center by exposure and development. Thereafter, by using the rest of the resist layer as a mask, half-etching is performed on the first conductive film 11 from the surface thereof. Thereby, the half-etching hole 25 having the curved side surface 26 is formed in the first conductive film 11. When the first conductive film 11 is made of copper, ferric chloride is used as an etching solution in the same manner. Subsequently, the resist layer is removed.

In the fifth step, conditions for the etching are determined according to the depth of the half-etching hole 25 to be formed. Thereby, the half-etching is controlled, taking into consideration the time required for the half-etching, on the basis of the speed thereof.

Furthermore, as shown in FIG. 4A, chemical etching is also performed on the second conductive film 12. The first and second conductive films 11 and 12 on the insulative substrate 10 are covered again respectively with resist layers (not illustrated). Then, a strip-shaped pattern, and a convex pattern on the left side of the center, which are shown in FIG. 2B, are formed on the second conductive film 12 by exposure and development. Thereafter, by using the rest of the resist layer as a mask, the second conductive film 12 is etched, and thereby an isolating groove 28 is formed. In this manner, a large number of patterns of cells are formed in a matrix. When the second conductive film 12 is made of copper, ferric chloride is used as an etching solution in the same manner. Subsequently, the resist layer is removed. It should be noted that the cell patterns of the second conductive film 12 are connected to one another by a connection pattern 29 (see FIG. 2B). This is because the second conductive film 12 will be used as a common electrode when conductive metal layers are formed by plating in the next step.

In the sixth step of the embodiment of the present invention, as shown in FIG. 4B, conductive metal layers 23a, 23b and 23c, which are bondable, are selectively deposited by plating respectively on the surfaces of the through-hole electrode 21a, the half-etching hole 25 and the through-hole electrode 21b.

In the sixth step, electrolytic plating is performed by using, as the common electrode, the cell patterns of the second conductive film 12 connected to one another. By the electrolytic plating, the conductive metal layers, which are bondable, are selectively deposited respectively on the surfaces of the half-etching hole 25 and the through-hole electrodes 21a and 21b in the cell pattern of the first conductive film 11 which is electrically connected to the cell patterns of the second conductive film 12 through the through-hole electrodes 21a to 21f. For the conductive metal layers, any one of gold, silver and nickel is selected. In most cases, silver plating layers 23a, 23b and 23c are provided, and thereby, wire bonding with metallic wires can be performed.

In the seventh step of the embodiment of the present invention, as shown in FIG. 4C, the light emitting element 31 is bonded and fixed to the bottom of the half-etching hole 25 of each cell.

In the seventh step, a chip of the light emitting element 31 is bonded and fixed to the bottom of the half-etching hole 25 with an adhesive 33 of an insulating epoxy resin or the like. On the upper surface of the light emitting element 31, there are an anode electrode and a cathode electrode. The lower surface of the light emitting element 31 is bonded and fixed to the half-etching hole 25 while being electrically insulated from the first conductive film 11. A chip mounter is used for bonding and fixing the light emitting element 31. It should be noted that, when a conductive paste is used as the adhesive 33, the cathode is taken out from the first conductive film 11.

In the eighth step of the embodiment of the present invention, as shown in FIG. 4C, the electrodes (not illustrated) of the light emitting element 31 are connected respectively to the conductive metal layers 23a and 23c by wire bonding with metallic wires 30.

In the eighth step, the electrodes of the light emitting element 31 are connected respectively to the conductive metal layer 23a and 23c on the through-hole electrodes 21a and 21b with the metallic wires 30 of gold. This connection is performed with thermosonic bonding by using a bonder, while the positions of the electrodes are recognized by pattern recognition. Due to the half-etching hole 25, the electrodes of the light emitting element 31 and the conductive metal layers 23a and 23c are formed approximately in the same plane with no difference in height. Accordingly, the wire bonding with the metallic wires 30 can be efficiently performed.

In the ninth step of the embodiment of the present invention, as shown in FIG. 4C, the light emitting element 31 and the metallic wires 30 are covered with a transparent resin 32.

In the ninth step, the light emitting element 31 and the metallic wires 30 are covered with the transparent resin 32. Accordingly, the light emitting element 31 and the metallic wires 30 are protected from an ambient air. Moreover, the transparent resin 32 also serves as a convex lens for taking light out.

In the tenth step of the embodiment of the present invention, as shown in FIG. 5, an individual light emitting device is divided in each cell by dicing.

In the tenth step, a large number of cells, which are arranged in a matrix on the insulative substrate 10, are divided into individual completed light emitting devices by dicing. At this time, the connection pattern 29, which connects the cells of the second conductive film 12 (see FIG. 2B), is also cut into pieces. Accordingly, the cells of the second conductive film 12 are also electrically isolated from one another.

To be concrete, for the insulative substrate 10, a glass epoxy substrate having a size of 68 mm×100 mm is used. Around the periphery of the insulative substrate 10, a plurality of positioning holes 34 are provided. In the insulative substrate 10, a large number of strip-shaped cells are arranged in a matrix. The positioning holes 34 are used for positioning described in the foregoing steps.

According to the present invention, it is possible to mount the light emitting element on the half-etching hole provided by performing chemical etching on the first conductive film. As a result, heat dissipation can be significantly improved.

In addition, the conductive metal layer used in bonding, is formed on the concave curved surface on the side surface of the half-etching hole. Accordingly, the conductive metal layer on the concaved curved surface can be used as a reflector. The tilt angle of the curved surface can be determined as appropriate according to the thickness of the first conductive film and to the conditions for the chemical etching.

Moreover, according to the present invention, the thickness of the first conductive film can be determined in accordance with the thickness of the light emitting element. Accordingly, the light emitting element can be fit into the half-etching hole. As a result, light from the light emitting element can be efficiently reflected by the conductive metal layer provided on the side surface of the half-etching hole.

Furthermore, according to the manufacturing method of the present invention, the curved surface, which is to be a reflector, can be formed concurrently in the step of forming the half-etching hole in the first conductive film. Accordingly, it is not necessary to form a reflector in another step. As a result, the manufacturing process is simplified

Still furthermore, according to the manufacturing method of the present invention, the conductive metal layer deposited on the side surface of the half-etching hole is formed together with the conductive metal layer used for wire bonding provided on the through-hole electrode in the depositing step. For this reason, as a conductive metal for the conductive metal layers, one of gold, silver and nickel is selected, and is used for bonding as well as for forming the reflector. Accordingly, it is possible to omit a step of forming a metallic film used for a reflector, which has been required in a conventional manufacturing method. As a result, the manufacturing process is further simplified.

Moreover, according to the manufacturing method of the present invention, it is possible to adjust the depth of the half-etching hole and the tilt angle of the curved surface by selecting the thickness of the first conductive film. This makes it possible to form the half-etching hole in accordance with the height of the light emitting element. Accordingly, the half-etching hole can be designed in accordance with the size of the light emitting element. As a result, it is possible to provide a curved surface having a high reflection efficiency. In addition, by forming the surface of the electrode of the light emitting element and the surface of the first conductive film in the same plane, the wire bonding with the metallic wire can be facilitated.

Furthermore, according to the manufacturing method of the present invention, a large number of cells each having a strip shape are arranged in a matrix. This makes it possible to manufacture a large number of light emitting devices at the same time. Moreover, this also makes it possible to form reflectors, which is essential, in the first conductive film.

What is claimed is:

1. A light emitting device comprising:
an insulating substrate comprising a first surface and a second surface opposite from the first surface;
a first conductive film disposed on the first surface and having a dent portion comprising a bottom and sidewall and denting toward the substrate;
a second conductive film disposed on the second surface and thinner than the first conductive film;
a light emitting element disposed in the dent portion of the first conductive film;
a through hole electrode disposed in a through hole formed in the substrate and connecting the first and second conductive films;
a first metal layer disposed on the sidewall of the dent portion so as to reflect light emitted from the light emitting element;
a second metal layer disposed on a top surface of the through-hole electrode; and
a metal wire connecting an electrode of the light emitting element and the second metal layer.

2. The light emitting device of claim 1, wherein the bottom of the dent portion is located in a position half way through a thickness of the first conductive film.

3. The light emitting device of claim 1, wherein a lateral dimension of the bottom of the dent portion is a half of a lateral dimension of the dent portion.

4. The light emitting device of claim 1, wherein a top surface of the light emitting element and a top surface of the first conductive film are at the same level.

5. The light emitting device of claim 1, wherein the first and second conductive films are made of copper, and each of the first and second metal layers is made of gold, silver or nickel.

6. A method of manufacturing a light emitting device, comprising:
providing an insulating substrate comprising a first conductive film disposed on a first surface thereof and a second conductive film disposed on a second surface thereof and thinner than the first conductive film;
forming a plurality of through holes in the substrate so as to penetrate though the substrate and the first and second conductive films;
forming a plurality of through hole electrodes in corresponding through holes by plating so as to connect electrically the first and second conductive films;
etching the first conductive film to define a plurality of cells;
forming a hole in the first conductive film for each of the cell;
depositing by plating a metal for bonding on a top surface of each of the through hole electrodes and a surface of each of the holes;
attaching a light emitting element to each of the holes on which the metal for bonding is deposited;
bonding, in each of the cells, an end of a metal wire to an electrode of the light emitting element and another end of the metal wire to a corresponding through hole electrode on which the metal for bonding is deposited;
covering the light emitting elements and the metal wires with a resin; and
cutting the substrate so as to produce separated light emitting devices.

7. The method of claim 6, wherein the first and second conductive films are made of copper, and the through-hole electrodes are formed by copper plating.

8. The method of claim 6, wherein each cell is formed into a rectangular shape, and the cells are arranged in a matrix form.

9. The method of manufacturing of claim 8, further comprising partnering the second conductive film to reflect the matrix form after the formation of the holes.

10. The method of claim 6, wherein the deposition of the metal for bonding comprises electrolytic plating of gold, silver or nickel using the second conductive film as a common electrode.

11. The method of claim 6, wherein the electrodes of the light emitting elements and the metal for bonding deposited on the through hole electrodes are on the same level at the time of the bonding of the metal wire.
